(19) United States
(12) Patent Application Publication
(10) Pub. No.: US 2010/0244911 A1
(43) Pub. Date: Sep. 30, 2010

(54) SUPPLY CIRCUITRY FOR SLEEP MODE

(75) Inventors: Romuald Soileux, Grenoble (FR); Sébastien Gaubert, Brignoud (FR)

Correspondence Address: Howard IP Law Group, P.O. Box 226, Fort Washington, PA, 19034, US

(73) Assignee: Dolphin Integration, Meylan (FR)

(21) Appl. No.: 12/728,796

(22) Filed: Mar. 22, 2010

(30) Foreign Application Priority Data
Mar. 24, 2009 (FR) 09/51874

(51) Int. Cl. H03L 7/00

(52) U.S. Cl. 327/143

(57) ABSTRACT

The invention concerns a supply circuitry system and method, including a supply circuitry arranged to control a power-up phase at the end of a sleep period of a circuit region of an integrated circuit, the supply circuitry comprising: first and second switches coupled between a supply rail and a supply node of the circuit region, the supply rail being coupled to receive a supply voltage (VDD) from a power supply unit; a comparator arranged to provide an output based on a comparison between a voltage at the supply node (VDD_INT) and a reference voltage (VREF); and control circuitry coupled to control terminals of the first and second switches and arranged to activate the first switch at the start of the power-up phase, and to activate the second switch once the output of the comparator indicates that the voltage at the supply node is greater than the reference voltage.

### RELATED APPLICATIONS

This application claims the benefit of French application Ser. No. 09/51874, filed Mar. 24, 2009, the entire disclosure of which is incorporated herein by reference in its entirety.

### FIELD OF THE INVENTION

The present invention relates to supply circuitry and a method for supplying a circuit region of an integrated circuit, and in particular to a supply circuit for supplying a voltage during a power-up phase of the circuit region.

### BACKGROUND OF THE INVENTION

In order to lower the power consumption of integrated circuits, it has been proposed to allow certain regions of integrated circuit to power-down while not in use. This is generally known as a sleep mode, and involves disconnecting these regions of the circuit from the supply voltage of the integrated circuit.

A problem with providing a sleep mode for a circuit region of an integrated circuit is that for a short period during power-up after a sleep period, the current to the circuit region may become very high, leading to a drop in the supply voltage often referred to as IR drop. Such a fall in the supply voltage is undesirable as this may affect other areas of the integrated circuit, such as memory devices. In some cases the supply voltage drop may lead to a loss in functionality of part of the circuit.

### SUMMARY OF THE INVENTION

According to one aspect of the present invention, there is provided supply circuitry arranged to control a power-up phase at the end of a sleep period of a circuit region of an integrated circuit, the supply circuitry comprising: first and second switches coupled between a supply rail and a supply node of the circuit region, the supply rail being coupled to receive a supply voltage from a power supply unit; a comparator arranged to provide an output based on a comparison between a voltage at the supply node and a reference voltage; and control circuitry coupled to control terminals of the first and second switches and arranged to activate the first switch at the start of the power-up phase, and to activate the second switch once the output of the comparator indicates that the voltage at the supply node is greater than the reference voltage.

According to an embodiment of the present invention, the reference voltage is generated from the supply voltage.

In another embodiment, the supply circuit further comprises an element, for example a diode, coupled between the supply voltage and the comparator for providing the reference voltage.

According to another embodiment, the first switch is activated by a first control signal and the comparator is also activated by the first control signal.

According to another embodiment, the supply circuitry further comprises an activity control unit arranged to generate a power-down signal to the control circuitry indicating when a sleep period is to be started and when a sleep period is to be ended.

According to another embodiment, the control circuitry is arranged to generate an acknowledgement signal to the activity control unit when the output of the comparator indicates that the voltage at the supply node is greater than the reference voltage.

According to another embodiment, in addition to the circuit region, the activity control unit is coupled to at least one further circuit region for controlling the start and end of a sleep period of the at least one further circuit region.

According to another embodiment, the activity control unit is coupled to the power supply unit and is arranged to indicate to the power supply unit when any of the circuit regions has started or is to end a sleep period.

According to another embodiment, the supply circuitry further comprises a third switch coupled between the supply rail and the supply node of the circuit region, and a further comparator arranged to provide an output to the control circuitry based on a comparison between the voltage at the supply node and a further reference voltage.

According to a further aspect of the present invention, there is provided an electronic device comprising an integrated circuit comprising a plurality of circuit regions; a power supply unit; and the above supply circuitry arranged to control sleep periods of the plurality of circuit regions.

According to a further aspect of the present invention, there is provided a method of controlling a power-up phase at the end of a sleep period of a circuit region of an integrated circuit, the integrated circuit comprising first and second switches coupled between a supply rail and a supply node of the circuit region, the supply rail being coupled to receive a supply voltage from a power supply unit, wherein the first and second switches are deactivated during the sleep period, the method comprising: activating by control circuitry the first switch and not the second switch at the start of the power-up phase; comparing by a comparator a voltage at the supply node with a reference voltage; and activating the second switch when the voltage at the supply node is greater than the reference voltage.

According to one embodiment, the method further comprises, before activating the first switch, generating by an activity control unit a power-up signal indicating that the sleep period is to be ended; and when the voltage at the supply node is greater than the reference voltage, providing by the control circuitry an acknowledgement signal to the activity control unit.

According to another embodiment, the method further comprises, prior to the step of generating the power-up signal, generating a warning signal to the power supply unit indicating that the sleep period of the circuit region is to be ended.

According to another embodiment, the method further comprises generating a warning signal by control circuitry if the voltage at the supply node is lower than the reference voltage while the second switch is activated.

### BRIEF DESCRIPTION OF THE DRAWINGS

The foregoing and other purposes, features, aspects and advantages of the invention will become apparent from the following detailed description of embodiments, given by way of illustration and not limitation with reference to the accompanying drawings, in which:

FIG. 1 illustrates an integrated circuit according to an embodiment of the present invention;

FIG. 2 illustrates timing signals of the integrated circuit of FIG. 1;

FIG. 3 illustrates an islet of the integrated circuit of FIG. 1 in more detail according to an embodiment of the present invention;

FIG. 4 illustrates timing signals of the islet of FIG. 3 according to an embodiment of the present invention;

FIG. 5 illustrates an islet of the integrated circuit of FIG. 1 in more detail according to another embodiment of the present invention; and

FIG. 6 illustrates timing signals of the islet of FIG. 5 according to an embodiment of the present invention.

### DETAILED DESCRIPTION OF THE PREFERRED EMBODIMENTS

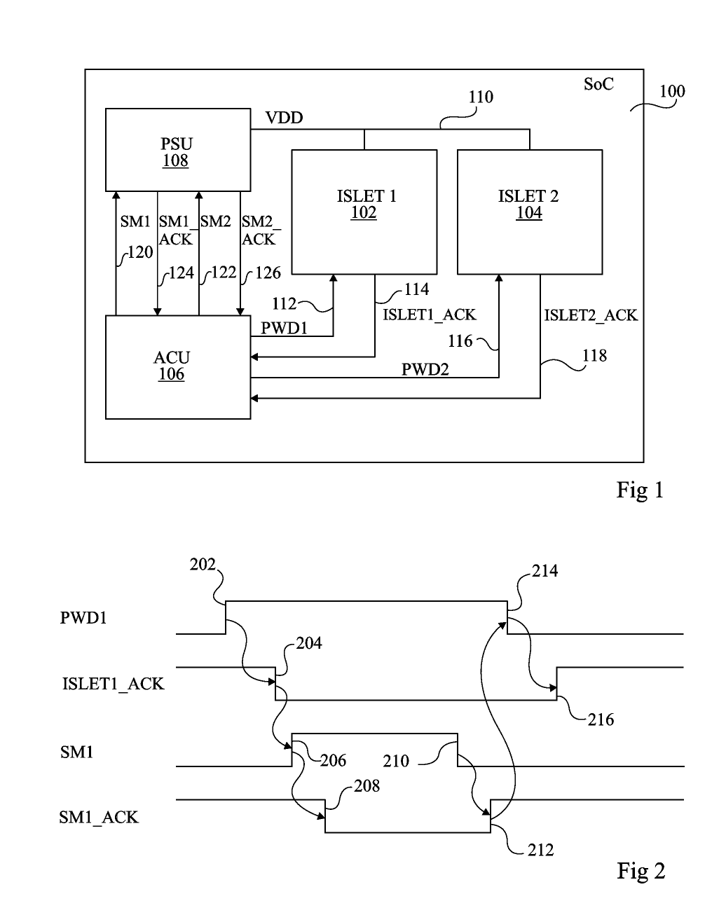

FIG. 1 illustrates an integrated circuit (IC) 100, which is for example a system on chip (SoC). IC 100 may be part of an electronic device such as a personal computer, laptop computer, set-top box, or a portable device such a mobile telephone, digital camera, portable games console, global positioning device, etc.

IC 100 comprises an islet 102 (ISLET1) and an islet 104 (ISLET2). While just two islets have been represented, a greater number of islets may be provided. Islets are regions of the integrated circuit that perform one or more functions, and which correspond to circuit regions that may be treated independently from each other for power supply purposes. In particular, islets do not necessarily relate to physically separate regions of the integrated circuit, but rather to circuits that may be powered down during a sleep mode while other portions of the integrated circuit continue to function. Thus an islet may be defined as having a single power supply, and a single activation signal supplied to it in order to activate or deactivate it. Generally, an islet comprises outputs that may be isolated during power supply changes, such as upon entering sleep mode, during the sleep mode, and/or at the end of the sleep mode. This is because the output state of the islet at these times may be uncertain, and isolating the outputs avoids invalid states propagating to other logic.

IC 100 comprises an activity control unit (ACU) 106 coupled to each of the islets 102 and 104. ACU 106 is also coupled to a power supply unit (PSU) 108, which provides a DC supply voltage VDD to the islets 102 and 104 via a supply rail 110. The PSU 108 for example comprises a DC to DC converter, entirely or partially integrated on a chip.

ACU 106 provides a power-down control signal PWD1 on a line 112 to islet 102, and receives from islet 102 an acknowledgement signal ISLET1_ACK on a line 114. In a similar fashion, ACU 106 provides a power-down signal PWD2 on line 116 to the islet 104, and receives from the islet 104 an acknowledgement signal ISLET2_ACK on a line 118.

ACU 106 also provides sleep mode signals SM1 and SM2 relating to islet 102 and islet 104 respectively to PSU 108 on respective lines 120 and 122. PSU 108 provides corresponding acknowledgement signals SM1_ACK and SM2_ACK on lines 124 and 126 respectively back to ACU 106.

Operation of the circuitry of the integrated circuit 100 of FIG. 1 will now be described with reference to the timing diagrams of FIG. 2.

The timing diagrams of FIG. 2 show an example of the timing signals PWD1, ISLET1_ACK, SM1 and SM1_ACK, which relate to islet 102 of FIG. 1. A similar sequence of timing signals can be used to activate or deactivate other islets of the circuit of FIG. 1.

The power-down signal PWD1 is for example low when the islet 102 is active, and operating normally. When it is desired that islet 102 is powered-down, signal PWD1 is asserted high, as shown by edge 202 in FIG. 2. Control circuitry within islet 102 (not shown in FIG. 1) responds accordingly, by disconnecting the islet 102 from the supply rail VDD. Once completed, an acknowledgement signal is provided on line 114, indicated for example by a change of state, as shown by falling edge 204.

When the acknowledgement signal ISLET1_ACK is received by the ACU 106, the ACU 106 asserts the sleep mode signal SM1 on line 120 to the PSU 108, as shown by rising edge 206 in FIG. 2. This signal indicates to the PSU 108 that islet 102 has entered the sleep mode. In response, the PSU 108 may for example adapt its supply circuitry to the updated requirements. In particular, due to the reduced consumption of islet 102, parts of the PSU 108 may be deactivated to save power.

PSU 108 acknowledges the sleep mode of islet 102 by providing the acknowledgement signal SM1_ACK, in the example of FIG. 2 indicated by a falling edge 208 of this signal.

At the end of the sleep mode, when the islet 102 is to be reactivated, the ACU 106 first brings low the sleep mode signal SM1, as shown by edge 212 in FIG. 2. This forewarns the PSU 108 that islet 102 will be powered again, and PSU 108 for example responds by activating additional circuitry to meet the anticipated extra power requirements of islet 102. PSU 108 then acknowledges the intended end of the sleep mode of islet 102, by asserting the acknowledgement signal SM1_ACK, as shown by rising edge 212 in FIG. 2.

The ACU 106 then brings low the power-down signal PWD1 to islet 102, as represented by the falling edge 214, indicating to islet 102 that it is to be reactivated. Control circuitry in islet 102 responds by reconnecting the islet to the supply rail VDD, and then once the functional circuitry in islet 102 is operating normally again, the acknowledgement signal ISLET1_ACK on line 114 is asserted, as shown by rising edge 216.

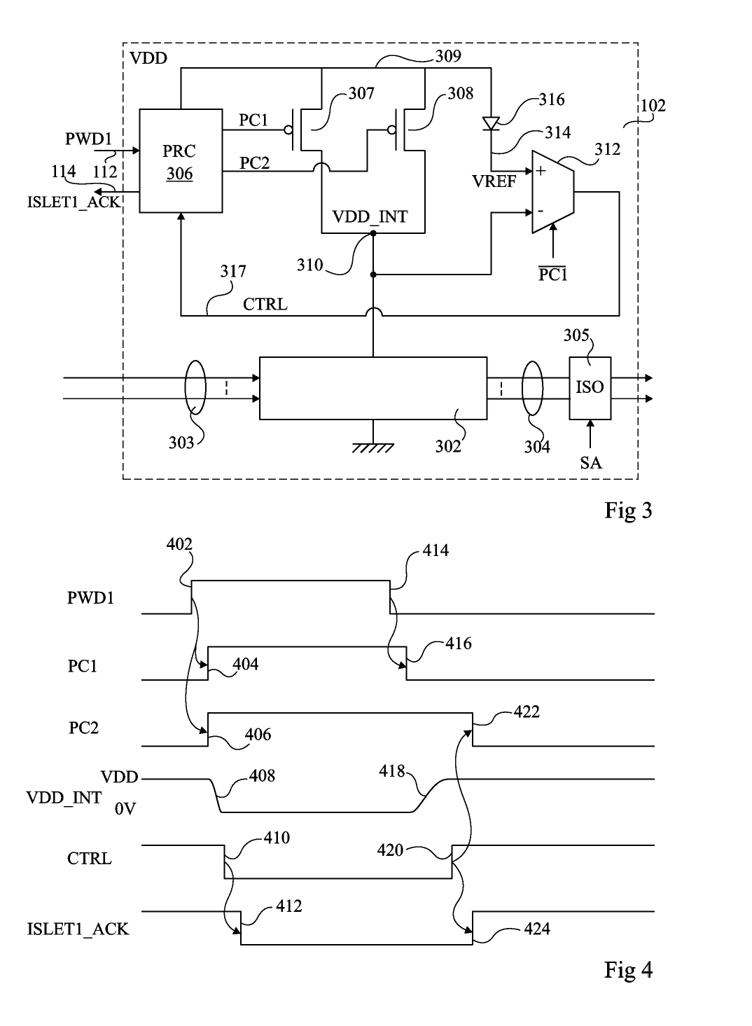

FIG. 3 illustrates islet 102 in more detail according to one example. Islet 102 comprises circuitry 302, representing the functional circuitry of the islet for performing a function, such as a logic function, a memory function, or other function that can be powered-down during a sleep mode. Circuitry 302 comprises inputs 303 coupled for example to other islets or circuitry of the integrated circuit. The circuitry 302 also comprises outputs 304 coupled for example to other islets or circuitry of the integrated circuit via an isolation unit 305. The isolation unit 305 isolates the outputs 304 during the sleep mode and during power-up or power-down of the islet, to avoid invalid data signals propagating to other circuitry.

Islet 102 also comprises a power retention controller (PRC) 306, which receives from the ACU 106 the power-down signal PWD1 on line 112 and provides to the ACU 106 the acknowledge signal ISLET1_ACK on line 114. PRC 306 generates power control signals PC1 and PC2. Signal PC1 is coupled to the gate terminal of a P-channel MOS transistor 307, while signal PC2 is coupled to the gate terminal of a P-channel MOS transistor 308. Transistors 307 and 308 are coupled between a supply rail and an intermediate voltage node 310. The intermediate voltage node 310 is coupled to the supply the circuitry 302, and provides the supply rail to this circuitry. Although not shown in FIG. 3, the supply rail 309 is coupled to the power supply unit 108 of FIG. 1 to receive a supply voltage VDD, for example at 1.8 V. Supply node 310 is at a voltage level VDD_INT, which is for example at VDD or very close thereto while circuitry 302 is powered, and at a low voltage such as ground during the sleep mode.

The isolation unit 305 is controlled by a signal SA generated by the power retention controller 306, which corresponds for example to the inverse of a power control signal PC1.

A comparator 312 comprises one input coupled to supply node 310 for receiving the voltage VDD_INT, and another input coupled to a line 314 for receiving a reference voltage VREF. Voltage VREF is for example slightly lower than the supply voltage VDD, and is supplied by a diode 316 coupled to the supply rail 309. The reference voltage is for example between 75 and 99 percent of the supply voltage VDD. The output signal CTRL of the comparator 312 is provided on line 317 to the PRC 306.

Operation of the circuitry of FIG. 3 will now be described with reference to the timing diagrams of FIG. 4.

The timing diagrams of FIG. 4 show an example of the timing signals PWD1, PC1, PC2, VDD_INT, CTRL and ISLET1_ACK, for the islet 102. Similar signals are for example used in islet 104.

As previously described, when the sleep mode is to be entered, the ACU 106 asserts the power-down signal PWD1. This is shown by edge 402 in FIG. 4. PRC 306 responds by asserting the signals PC1 and PC2, as shown by edges 404 and 406 in FIG. 4. This turns off transistors 307 and 308, disconnecting the supply node 310 from the supply rail 309, and disconnecting power from the circuitry 302. Thus, as show in FIG. 4 by the falling edge 408, the voltage VDD_INT at node 310 drops from VDD to 0 V. The output of the comparator 312, labeled CTRL, thus goes low shortly afterwards as shown by falling edge 410, and in response, the PRC block 306 generates and transmits the acknowledge signal ISLET1_ACK, by bringing this signal to the low state as shown by edge 412.

When islet 102 is to be powered up at the end of the sleep mode, the signal PWD1 is brought low again by the ACU 106, as shown by falling edge 414. In response, the PRC 306 brings the signal PC1 to the low state, as illustrated by the falling edge 416, but initially keeps the signal PC2 in the high state. This results in transistor 307 coupling the supply rail 309 to node 310, while transistor 308 remains non-conducting. Transistor 307 may be smaller than transistor 308, for example having a width of between one tenth and a quarter of the width of transistor 308. Thus only a limited current is allowed to flow from the supply rail 309 to the circuitry 302. This prevents current spikes that could cause a drop in the supply voltage VDD in the rest of the circuit.

Relatively slowly, the voltage VDD_INT at node 310 increases towards the supply voltage level VDD, as shown by rising edge 418 in FIG. 4. After a certain time period, the voltage VDD_INT reaches VDD, or very close to VDD and the output CTRL of comparator 312 goes high, as shown by edge 420 in FIG. 4. In response, PRC 306 controls the signal PC2 to go low, turning on transistor 308. PRC 306 also provides the acknowledgement signal ISLET1_ACK, as illustrated by the rising edge 424, to inform ACU 106 that power-up of islet 102 is complete.

When both transistors 307 and 308 are activated to couple together the supply rail 309 and supply node 310, preferably only a small resistance is present between the supply rail 309 and node 310, resulting in a negligible voltage drop across these transistors for most load currents.

The PRC block 306 is for example coupled directly to the supply rail 309, and is thus permanently powered, while the supply rail is at VDD and when the islet 102 enters the sleep mode. The comparator 312 is for example also coupled to the supply rail, but is controlled to be active only when PC1 is asserted low. Thus, as shown in FIG. 3, it for example receives the inverse of signal PC1 as an activation signal. Once PC2 has been asserted low, such that transistor 308 is conducting, the comparator 312 could be deactivated. However, in some embodiments the comparator 312 continues to operate, and serves to provide a warning signal in the case that the voltage at node 310 falls below the reference voltage VREF. This could indicate for example that circuitry 302 is drawing too much current, perhaps due to a fault. Such a warning signal could be provided to the ACU 106, or other circuitry of the integrated circuit.

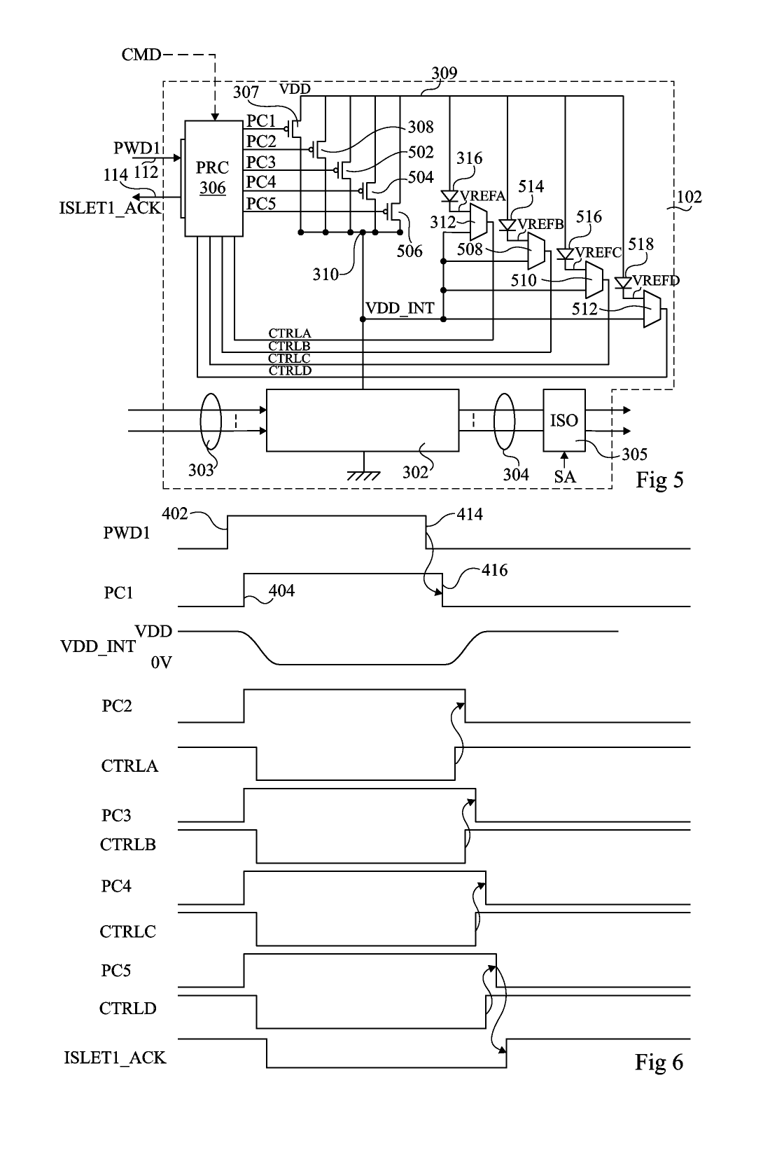

FIG. 5 illustrates the islet 102 according to an alternative embodiment. Features which are the same as those in the islet of FIG. 3 have been labeled with like reference numerals, and will not be described again in detail.

In the islet 102 of FIG. 5, in addition to transistors 307 and 308, a further three transistors 502, 504 and 506 are provided coupled in parallel with transistors 307 and 308 between the supply rail 309 and node 310. Transistors 502 to 506 receive power control signals PC3 to PC5 at their control terminals respectively, from the PRC 306. Furthermore, in addition to comparator 312, comparators 508, 510 and 512 are provided. Each of the comparators 312 and 508 to 512 receive at a positive input terminal a respective reference voltage VREFA, VREFB, VREFC and VREFD. Voltage VREFA is provided by diode 316, while voltages VREFB, VREFC and VREFD are provided by respective diodes 514, 516 and 518, each having its anode coupled to the supply voltage rail 309, and each being of a different size such that the reference voltages are slightly offset with each other. In this example, reference voltage VREFA is the lowest and VREFD the highest, and for example the values are VREFA=60%, VREFB=70%, VREFC=80% and VREFD=90% of the supply voltage VDD. A negative input of each comparator 312, 508, 510, 512 is coupled to the voltage node 310 to receive the voltage VDD_INT. The outputs of comparators 312 and 508 to 512 provide control voltages CTRLA to CTRLD respectively on feedback lines to the PRC 306. The PRC 306 optionally comprises a control input CMD coupled to the ACU 106 of FIG. 1.

One example of operation of the islet 102 of FIG. 5 will now be described with reference to the timing diagrams of FIG. 6.

The timing diagrams of FIG. 6 represent an example of the signals PWD1, PC1 and VDD_INT, which are the same as those of FIG. 4, and signals PCA to PC2D, CTRLA to CTRLD and ISLET1_ACK for islet 102 of FIG. 5. Similar signals are for example uses for islet 104.

When the power down signal PWD1 goes high, the power control signals PC1 to PC5 simultaneously go high, turning off all transistors 307, 308 and 502 to 506, and thereby turning off circuitry 302. This in turn causes the voltage VDD_INT to fall, and each of the control signals CTRLA to CTRLD to go low. In response, the acknowledgement signal is asserted by PRC 306 by bringing signal ISLET_1ACK low, which indicates that the power down has been completed.

When the power down signal PWD1 goes low again, indicating that the islet 102 is to power-up, initially only PC1 is for example brought low, activating transistor 307, and triggering a rise in the voltage VDD_INT at node 310. When the threshold determined by VREFA is reached, control signal CTRLA goes high, triggering the power control signal PC2 to go low, and activating transistor 308. Then, when the threshold determined by VREFB is reached, control signal CRTLB goes high, triggering the power control signal PC3 to go low, and activating transistor 502. The control signals CTRLC and CTRLD, rising one after the other when their respective thresholds are reached, triggering for example the fall of the power control signals PC4 and PC5, and all the transistors are activated. Once control signal CTRLD goes high, the acknowledgement signal is asserted by the PRC 306, by bringing high ISLET1_ACK, indicating that power-up is completed.

In alternative embodiments, when the power down signal PWD1 goes low, the PC signals PC1 to PC5 may be activated in other combinations based on one or more of the control signals CTRLA to CTRLD. For example, initially the signals PC1 and PC2 are brought low together, and once the threshold determined by VREFB is reached, the signals PC3 to PC5 are brought low. According to a further alternative, the signal PC1 is initially brought low, and the remaining signals PC2 to PC5 are brought low once the threshold determined by VREFD is reached. As yet a further alternative, initially the signals PC1 and PC2 are brought low, and then once the threshold determined by VREFA is reached, the signals PC3 and PC4 are brought low, and then once the threshold determined by VREFB is reached, the signal PC5 is brought low.

Generally, the rise time of voltage VDD_INT is inversely proportional to the power used during power-up. In other words, the quicker the rise time, the higher the peak current. In some embodiments, the activation sequence of PC1 to PC5 based on one or more of signals CTRLA to CTRLD is controlled by the ACU 106, via the CMD input to PRC 306, according to the available power resources. For example, if ACU 106 determines that ISLET 104 is in sleep mode, it may allow ISLET 102 to power-up quickly, for example by bringing the signals PC1, PC2 and the signal PC3 low initially, and then bringing the signals PC4 and PC4 low when the threshold determined by CTRLA is reached. Alternatively, if for example ACU 106 determines that both ISLET 102 and 104 are to be powered-up at the same time, relatively slow rise times are used for ISLET 102, for example by initially only bringing the signal PC1 low, and then bringing only the signal PC5 low once the threshold determined by VREFD is reached. In some embodiments, the ACU 106 may alter the activation sequence of signals PC1 to PC5 part-way through power-up, if the power resource usage changes.

Transistors 308, 502, 504, 506 are for example of the same dimensions, or alternatively these transistors could have different dimensions, for example different widths, such that the transconductance of the activated transistors at the different stages of power-up can be more accurately controlled, by activating different combinations of the transistors.

An advantage of the circuitry described herein comprising two independently activated transistors for supplying the islet is that one of the transistors can be chosen to have a small size to limit the current on power-up of the islet, while the other transistor can be chosen to have a larger size, to reduce resistance between the supply rail and the islet during supply of the islet. Furthermore, by providing a comparator to monitor the voltage of the supply node to the islet, the second transistor can be activated at the moment when the islet has stabilized, thereby preventing the second transistor from being activated too early nor unnecessarily late. Activating the second transistor too early could result in a current spike, leading to a drop in VDD. Activating the second transistor unnecessarily late will lead to a less ideal conductance during the active mode.

Having thus described at least one illustrative embodiment of the invention, various alterations, modifications and improvements will readily occur to those skilled in the art.

For example, while in the embodiments described herein the reference voltage is provided by a diode coupled to the supply rail, in alternative embodiments it could be provided by alternative circuitry, such as a potential divider.

Furthermore, it will be apparent to those skilled in the art that a short delay could be introduced by PRC 306 between the output of one or more comparators 316, or 316A to 316D going high, and the activation of the transistors by the corresponding power control signals PC2 or PC2A to PC2D. Furthermore, delayed versions of any of the power control signals PC2 or PC2A could used to activate additional transistors coupled in parallel with the transistors 307, 308 and 308A to 308D.

Furthermore, while the use of two transistors 307 and 308 between the supply rail and the supply node of the islet has been described, it will be apparent to those skilled in the art that either of these transistors could be formed of an number of transistor coupled in parallel, controlled by the same signal (PC1 or PC2). Furthermore, in alternative embodiments these transistors, which are shown as P-channel MOS transistors in the figures, could be implemented as N-channel MOS transistors or other type of switch. The control signals PC1 and PC2 may be adapted accordingly, for example to activate the switches when in the high state rather than the low state.

While the PSU has been described as comprising a DC to DC converter, in alternative embodiments the PSU could be an AC to DC converter, one or more battery cells, or an alternative power source.

What is claimed is:

1. Supply circuitry for controlling a power-up phase at the end of a sleep period of a circuit region of an integrated circuit, the supply circuitry comprising:
first and second switches coupled between a supply rail and a supply node of the circuit region, the supply rail being coupled to receive a supply voltage from a power supply unit;
a comparator arranged to provide an output based on a comparison between a voltage at the supply node and a reference voltage; and
control circuitry coupled to control terminals of the first and second switches and arranged to activate the first switch at the start of the power-up phase, and to activate the second switch once the output of the comparator indicates that the voltage at the supply node is greater than the reference voltage.

2. The supply circuitry of claim 1, wherein the reference voltage is generated from the supply voltage.

3. The supply circuitry of claim 2, further comprising an element coupled between the supply voltage and the comparator for providing the reference voltage.

4. The supply circuitry of claim 3, wherein the element is a diode.

5. The supply circuitry of claim 1, wherein the first switch is activated by a first control signal and the comparator is also activated by the first control signal.

6. The supply circuitry of claim 1, further comprising an activity control unit arranged to generate a power-down signal to the control circuitry indicating when a sleep period is to be started and when a sleep period is to be ended.

7. The supply circuitry of claim 6, wherein the control circuitry is arranged to generate an acknowledgement signal to the activity control unit when the output of the comparator indicates that the voltage at the supply node is greater than the reference voltage.

8. The supply circuitry of claim 6, wherein, in addition to the circuit region, the activity control unit is coupled to at least one further circuit region for controlling the start and end of a sleep period of the at least one further circuit region.

9. The supply circuitry of claim 8, wherein the activity control unit is coupled to the power supply unit and is arranged to indicate to the power supply unit when any of the circuit regions has started or is to end a sleep period.

10. The supply circuitry of claim 1, further comprising a third switch coupled between the supply rail and the supply node of the circuit region, and a further comparator arranged to provide an output to the control circuitry based on a comparison between the voltage at the supply node and a further reference voltage.

11. In an integrated circuit having a plurality of circuit regions, and a power supply unit, a supply circuit coupled to the power supply unit and configured to control sleep periods of the plurality of circuit regions, comprising:
first and second switches coupled between a supply rail and a supply node of at least one of the circuit regions, the supply rail being coupled to receive a supply voltage from the power supply unit;
a comparator arranged to provide an output based on a comparison between a voltage at the supply node and a reference voltage; and
control circuitry coupled to control terminals of the first and second switches and arranged to activate the first switch at the start of the power-up phase, and to activate the second switch once the output of the comparator indicates that the voltage at the supply node is greater than the reference voltage.

12. A method of controlling a power-up phase at the end of a sleep period of a circuit region of an integrated circuit, the integrated circuit comprising first and second switches coupled between a supply rail and a supply node of the circuit region, the supply rail being coupled to receive a supply voltage from a power supply unit, wherein the first and second switches are deactivated during the sleep period, the method comprising:
activating by control circuitry the first switch, and not the second switch, at the start of the power-up phase;
comparing a voltage at the supply node with a reference voltage; and
activating the second switch when the voltage at the supply node is greater than the reference voltage.

13. The method of claim 12, further comprising:
before activating the first switch, generating by an activity control unit a power-up signal indicating that the sleep period is to be ended; and
providing by the control circuitry an acknowledgement signal to activity control unit when the voltage at the supply node is greater than the reference voltage.

14. The method of claim 13, further comprising, prior to the step of generating the power-up signal; generating a warning signal to the power supply unit indicating that the sleep period of the circuit region is to be ended.

15. The method of claim 12, further comprising:
after the step of activating the second switch, comparing the voltage at the supply node with the reference voltage and generating a warning signal if the voltage at the supply node is lower than the reference voltage.
